(19) United States
(12) Patent Application Publication
(10) Pub. No.: US 2016/0230282 A1
(43) Pub. Date: Aug. 11, 2016

(54) HEATER MEMBER AND SUBSTRATE PROCESSING APPARATUS HAVING THE SAME

(71) Applicant: KOOKJE ELECTRIC KOREA CO., LTD., Chungcheongnam-do (KR)

(72) Inventors: Hong Joo BANG, Cheonan-si (KR); Sang Yeon KIM, Cheonan-si (KR); Dong Hwa SHIN, Cheonan-si (KR); Min Seok KIM, Cheonan-si (KR); Jin Young YANG, Cheonan-si (KR)

(21) Appl. No.: 15/022,729

(22) PCT Filed: Mar. 21, 2014
(86) PCT No.: PCT/KR2014/002385

§ 371 Date: Mar. 17, 2016

(30) Foreign Application Priority Data
Sep. 23, 2013 (KR) 10-2013-0112841

(51) Int. Cl. C23C 16/48; C23C 16/458; C23C 16/44; C23C 16/455

(52) U.S. Cl. CPC C23C 16/481; C23C 16/45544; C23C 16/4585; C23C 16/4412

(57) ABSTRACT

The present invention relates to a substrate processing apparatus. The substrate processing apparatus according to the present invention comprises: a processing chamber; substrate susceptor, installed in the processing chamber, which rotates in connection with a rotary shaft, a plurality of substrates being disposed on the same plane thereof; a heater member located on the lower surface of the substrate susceptor; and a spraying member for spraying a gas onto the entire processing surface of the substrate at a position corresponding to each of the plurality of substrates disposed on the substrate susceptor, wherein the heater member has an inner space in which heating wires for heating the substrate susceptor are arranged in a plurality rows of verticality and horizontality in a concentric circle based on the rotary shaft of the substrate susceptor.

### TECHNICAL FIELD

The present invention relates to a substrate processing apparatus, and more specifically relates to a substrate processing apparatus having a heater member.

### BACKGROUND ART

In a deposition process for manufacturing semiconductor devices, an atomic layer deposition method has been introduced to improve conformability of a deposition layer. The atomic layer deposition method forms a deposition layer with desired thickness by repeating units of a reaction cycle by which a layer is deposited at about atomic layer thickness, but the atomic layer deposition method is lower than a chemical vapor deposition (CVD) method or a sputtering method in deposition rate and requires a lot of time for growing a layer of desired thickness, thereby productivity is deteriorated.

Particularly, temperature uniformity of a susceptor is one of essential factors which determines thickness uniformity of the layer deposited on a substrate. However, a temperature declining phenomenon is occurred by a heat loss and an increase of substrate amount processed on the susceptor. In additional, corrosion of heater is occurred by a process gas permeation and performance deterioration of heater is occurred by an oxide deposition.

### DISCLOSURE OF THE TECHNICAL PROBLEM

Embodiments of the inventive concepts provide heater member capable of improving temperature uniformity and a substrate processing apparatus having the same.

Embodiments of the inventive concepts also provide a heater member which prevents a heating wire from drooping and twisting by thermal expansion of the heating wire and a substrate processing apparatus having the same.

Embodiments of the inventive concepts further provide a heater member which prevents heating wire corrosion by a process gas during processing and a substrate processing apparatus having the same.

Other aspects, advantages, and salient features of the disclosure will become apparent to those skilled in the art from the following detailed description, which, taken in conjunction with the annexed drawings, discloses various embodiments of the inventive concept.

### Technical Solution

According to embodiments of the inventive concepts, a substrate processing apparatus may include a process chamber; a substrate susceptor installed in the process chamber and connected with a rotation axis to be rotated, wherein a plurality of substrates are laid at the same level on the susceptor; a heater member disposed on a lower surface of the substrate susceptor; and a splay member splaying gas on an entire processing surface of the substrates from locations corresponding to the plurality of the substrates, wherein the heater member has an interior space, and heating wires for heating the substrate susceptor are arranged in a plurality rows of horizontality and verticality on concentric circles around the rotation axis in the interior space.

The heater member may further comprise heating wire supporters sustaining the heating wire to prevent the heating wire from drooping and twisting by thermal expansion of the heating wire.

The heating wire supporter may comprise concave support surface formed along a latitudinal direction of the heating wire to secure flexibility for the thermal expansion of the heating wire.

The heating wire supporter may comprise a support block; and a support bar having bar shape and formed on an upper surface of the support block. The support bar may be in point contact with the heating wire to minimize contact area with the heating wire, thereby preventing heat loss and preventing the heating wire supporter from broken by high heat of the heating wire.

The support bar may be formed of the same material as the heating wire.

The support bar may be provided along the latitudinal direction of the heating wire.

The heater member may further comprise a housing provided by an upper wall, a lower wall and sidewalls to isolate the interior space where the heating wire is arranged from an interior of the process chamber.

The heater member may further comprise a supply port provided to the lower wall and supplying purge gas into the interior space to prevent the process gas from permeating into the interior space.

The heater member may further comprise an exhaust port provided to the lower wall. The purge gas supplied into the interior space through the supply port may be exhausted through the exhaust port.

The heater member may comprise side holes provided to the sidewall of the housing. The purge gas supplied into the interior space through the supply port may be exhausted through the side holes.

The upper wall may be formed of quartz material capable of transmitting a radiant heat emitted from the heating wire.

A radiant heat transmission. space is formed between the substrate susceptor and the heater member to transmit heat of the heating wire by a radiation mode.

According to embodiments of the inventive concepts, a heat member may include a housing having an interior space provided by an upper wall, a lower wall and sidewalls an isolated from an exterior environment; and heating wires for heating the substrate susceptor arranged in plurality rows of horizontality and verticality on the concentric circle around a center of the substrate susceptor in the interior space.

The heater member may further comprise heating wire supporters sustaining the heating wire to prevent the heating wire from drooping and twisting by thermal expansion of the heating wire. The heating wire supporter may comprise a concave support surface formed along a latitudinal direction of the heating wire to secure flexibility for the thermal expansion of the heating wire.

The heater member may further comprise heating wire supporters sustaining the heating wire to prevent the heating wire from drooping and twisting by thermal expansion of the heating wire. The heating wire supporter may comprise a support block; and a support bar having bar shape and formed on an upper surface of the support block. The support bar may be in point contact with the heating wire to minimize contact area with the heating wire, thereby preventing heat loss and preventing the heating wire supporter from broken by high heat of the heating wire.

The heater member may further comprise a supply port supplying purge gas into the interior space to prevent the process gas from permeating into the interior space; and an exhaust port where the purge gas supplied into the interior space through the supply port is exhausted.

### Advantageous Effects

According to an embodiment of the inventive concepts, a variation of temperature distribution can be minimized.

According to an embodiment of the inventive concepts, thermal efficiency can be elevated.

According to and embodiment of the inventive concepts, temperature uniformity can be improved.

According to an embodiment of the inventive concepts, it can be prevented that drooping and twisting of a heating wire by thermal expansion of the heating wire.

According to an embodiment of the inventive concepts, it can be prevented that corrosion of the heating wire by process gas.

### BRIEF DESCRIPTION OF THE DRAWINGS

FIG. 1 illustrates an atomic layer deposition apparatus according to an embodiment of the inventive concepts.

FIGS. 2a and 2b are a perspective view and a cross sectional view illustrating a spay member of FIG. 1.

FIG. 3 is a perspective view illustrating a substrate susceptor of FIG. 1.

FIG. 4 is an important part view of a substrate processing apparatus illustrating a heater member.

FIG. 5 illustrates heating wires sustained by a heating wire supporter.

FIG. 6 illustrates a heating wire before and after thermal expansion.

FIG. 7 illustrates another embodiment of the heating wire supporter.

### BEST MODE FOR CARRYING OUT THE INVENTION

The inventive concepts will now be described more fully hereinafter with reference to the accompanying drawings, in which embodiments of the inventive concepts are shown. The advantages and features of the inventive concepts and methods of achieving them will be apparent from the following embodiments that will be described in more detail with reference to the accompanying drawings. In the drawings, embodiments of the inventive concepts exaggerated or simplified for clarity. In denoting reference numerals to elements of each drawing, the same reference numerals denote the same elements though the elements are shown in different drawings. In describing embodiments of the inventive concepts, descriptions for universally known elements or functions may be left out when the descriptions make obscure essential points of the inventive concepts.

### Embodiment

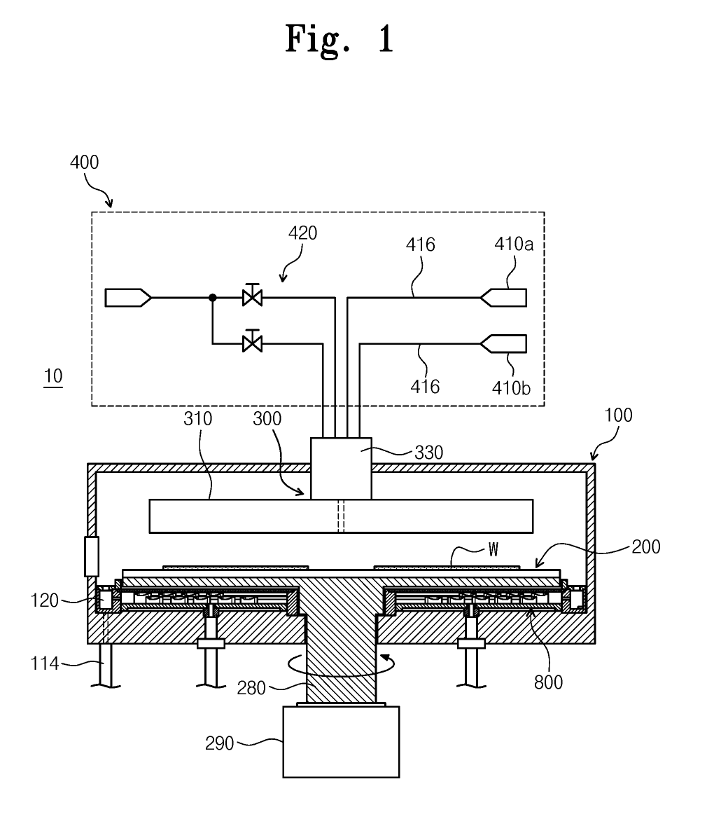

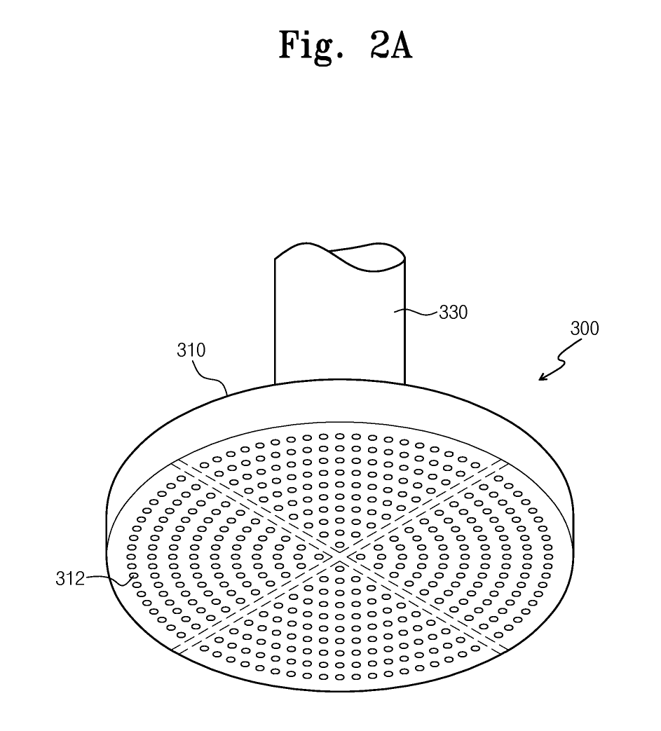

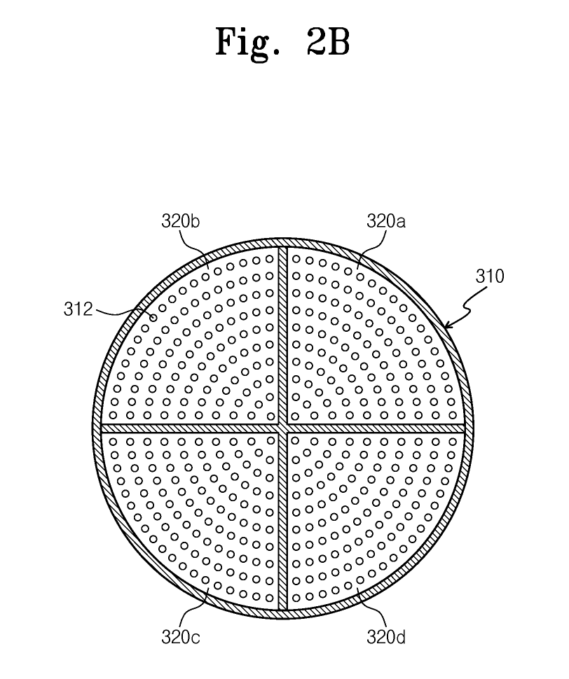

FIG. 1 illustrates an atomic layer deposition apparatus according to an embodiment of the inventive concepts. FIGS. 2a and 2b are a perspective view and a cross sectional view illustrating a spay member of FIG. 1. FIG. 3 is a perspective view illustrating a substrate susceptor of FIG. 1.

Referring to FIGS. 1 to 3, the atomic layer deposition apparatus 10 may include a process chamber 100, a substrate susceptor 200 which is a support member, a splay member 300, a supply member 400 and a heater member 800.

A gate 112 may be provided to a side of the process chamber 100. Substrates W may be loaded in and out through the gate 112 for processes. The process chamber 100 may include an exhaust duct 120 and an exhaust pipe 114 on the edge of its lower portion to exhaust reaction gas and purge gas supplied to the process chamber and a byproduct produced in an atomic layer deposition process. The exhaust duct 120 may be formed of ring shape which locates at the outside of the substrate susceptor 200. Not shown in drawings, it is obvious that the exhaust pipe 114 may be connected with a vacuum pump, and a pressure control valve and flow control valve may be equipped with the exhaust pipe 114.

As shown in FIGS. 1 to 2b, the splay member 300 may splay gas to each of four substrates disposed on the substrate susceptor 200. First and second reaction gas and purge gas may be provided to the splay member 300 from the supply member 400. The splay member 300 may include a head 330 with a first through a fourth baffles 320a through 320d and a shaft 330 supporting the head 310. The first through the fourth baffles 320a through 320d locates at positions corresponding to each substrate to splay supplied gas on an entire process surface of the substrates, and the shaft 330 is equipped through the upper center portion of the process chamber 100. The head 310 may have disk shape. The first through forth baffles 320a through 320d have discrete spaces therein for containing each of the gases. The first through the forth baffles 320a through 320d have fan shape divided at 90 degree intervals around the center of the head 310. Gases are supplied from the supply member 400 to each discrete spaces of the first through the forth baffles 320a through 320d. These gases are splayed through gas nozzles, thereby providing with the substrates. The first reaction gas may be supplied to the first baffle 320a, the second reaction gas may be supplied to the third baffle 320c, the purge gas for blocking mixture of the first reaction gas and the second reaction gas and purging unreacted gas is supplied to the second baffle 320b and the third baffle 320d between the first and the third baffles 320a and 320c.

For example, the first through the forth baffles 320a through 320d of the head 310 are formed as fan shape and disposed at 90 degree intervals. The inventive concepts are not limited to this, however, the first through the forth baffles 320a through 320d may be formed at 45 degree intervals or 180 degree intervals and the size of baffles may be different from each other according to purpose or feature of the process.

Referring to FIG. 1, the supply member 400 may include a first gas supply member 410a, a second gas supply member 410b and a purge gas supply member 420. The first gas supply member 410a may supply the first reaction gas for forming a predetermined thin layer on the substrate W to the first baffle 320a, the second gas supply member 410b may supply the second gas to the third baffle 320c and the purge gas supply member 420 may supply the purge gas to the second and the forth baffles 320b and 320d. The purge gas supply member 420 constantly supplies the purge as at regular flow rate, but the first gas supply member 410a and the second supply member 410b may flush the reaction gas filled in a high pressure finable tank (not shown) in a short time to spread on the substrate.

In this embodiment, two difference reaction gases are supplied using two gas supply members. However, a plurality of gas supply members may be applied to supply more than three different reaction gases according to feature of the process.

As shown in FIGS. 1 and 3, the substrate susceptor 200 may be installed at an interior space of the process chamber 100. For example, the substrate susceptor 200 may be formed of batch type where four substrates are disposed. The substrate susceptor may be formed of disk shape having an upper surface where a first through a fourth stage 212a through 212d is formed. The first and the fourth stages 212a through 212d formed at the substrate susceptor 200 may be formed of circular shape similar with shape of the substrates. The first through the fourth stages 212a through 212d may be formed on a concentric circle at 90 degree intervals around the center of the substrate susceptor 200.

The number of stages may be assigned the substrate susceptor 200 three or more than four instead of four.

The substrate susceptor 200 may be rotated by a drive member 290 which is connected with a rotation axis 280. The drive member 290 for rotating the substrate susceptor 200 may be a stepping motor in which an encoder capable of controlling rotational frequency and revolution speed of a drive motor is installed. The time of one cycle process (the first reaction. gas-the purge gas-the second reaction gas-the purge gas) of the splay member 300 may be controlled by the encoder.

Not shown in drawings, the substrate susceptor 200 may have a plurality of lift pins which lift up and down the substrates W from each of the stages. The lift fin lifts up and down the substrate W to separate the substrate W from the stage or put down the substrate W on the stage.

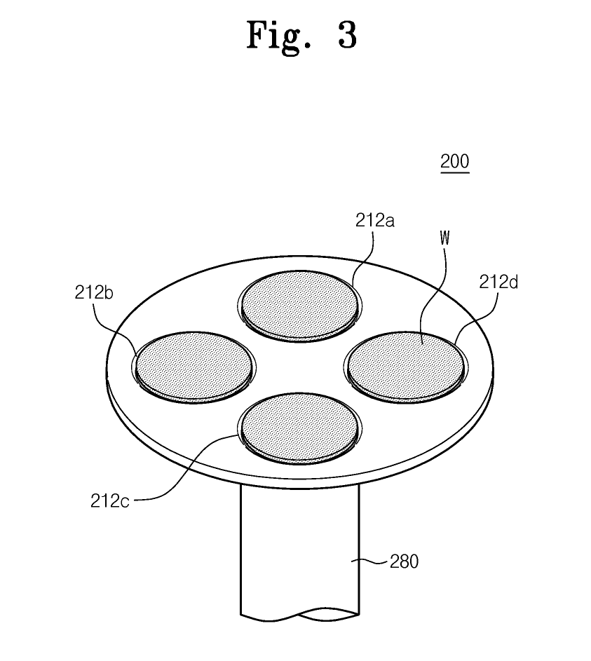

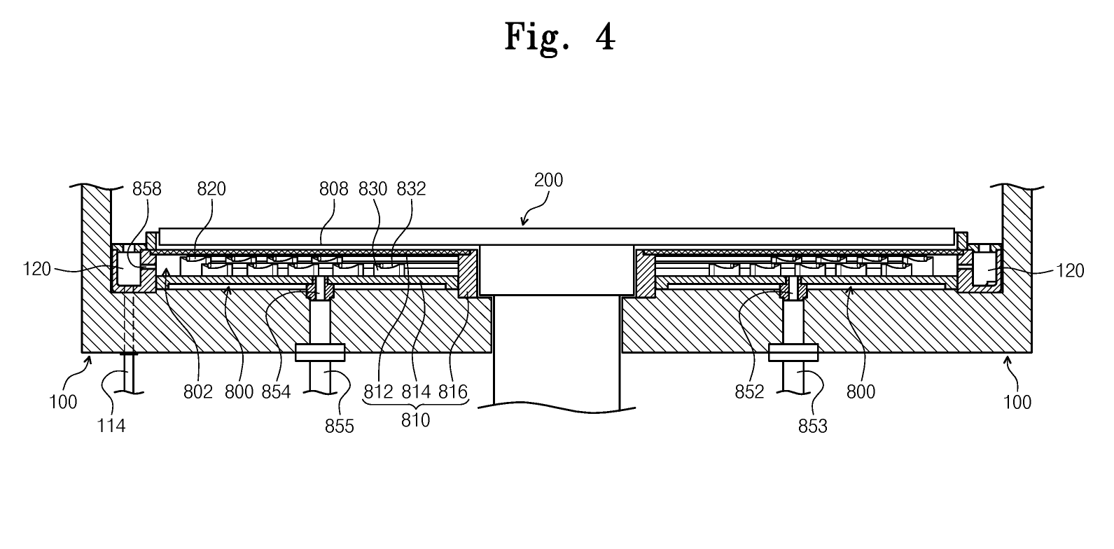

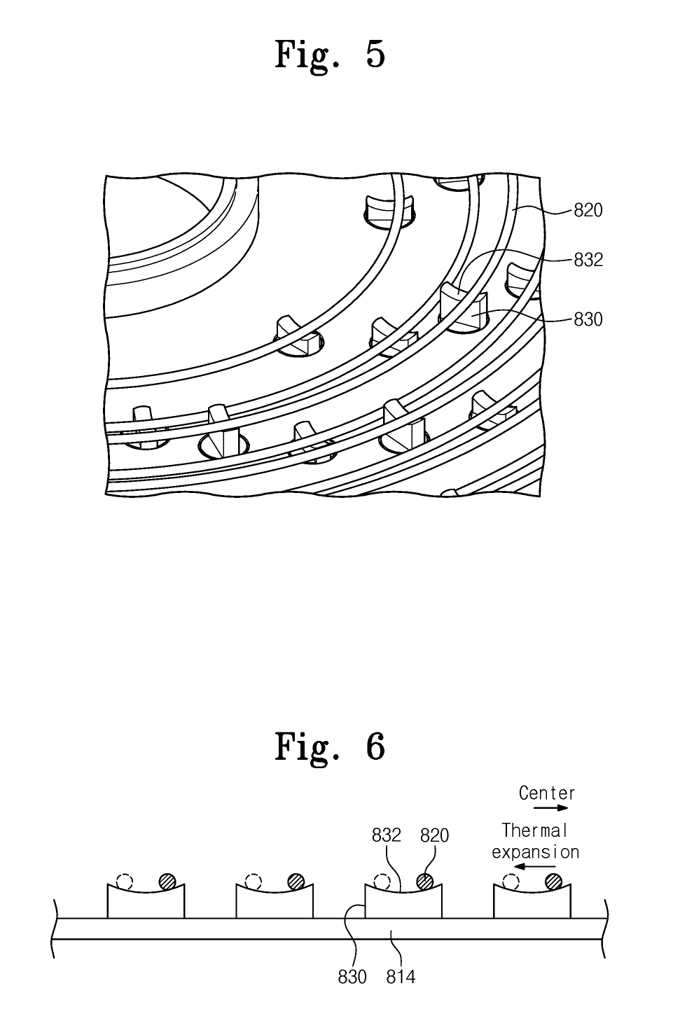

FIG. 4 is an important part view of a substrate processing apparatus illustrating a heater member, FIG. 5 illustrates heating wires sustained by a heating wire supporter and FIG. 6 illustrates a heating wire before and after thermal expansion.

Referring to FIGS. 4 and 5, the heater member 800 may be located under the substrate susceptor 200. The heater member 800 may apply heat to the substrate susceptor 200 to elevate temperture of the substrate up to a predetermined temperature which is process temperature. A gap of a few millimeters may be provided between the heater member 800 and the substrate susceptor 200. Thermal energy of the heater member may be transferred to the substrate susceptor by radiant mode not by conductive mode to improve temperature uniformity of the substrate susceptor 200.

The heater member 800 may include a housing 810, heating wires 820 and a heating wire supporter 830.

The housing 810 may have an interior space 802 isolated from an external environment, i.e., a process space of the process chamber. The interior space 802 may be provided by an upper wall 812, a lower wall 814 and sidewalls 816. The heating wires 820 may be installed at the interior space 802. The upper wall 812 may be formed of quartz material capable of transmitting a radiant heat from the heating wire 820.

A supply port 852 and an exhaust port 854 may be provided to the lower wall 814 of the housing 810. The supply port 852 may be connected with a supply line 853 which supplies the purge gas. Inner pressure of the housing may be maintained higher than pressure of the process chamber by the purge gas supplied through the supply port 852 to prevent the process gas from permeating into the interior space of the housing 810 during the process. The exhaust port 854 may be connected with an exhaust line 855. The purge gas supplied to the interior space through the supply port 852 may be exhausted to the exhaust line 855 through the exhaust port 854.

The exhaust of the purge gas in the housing 810 may be implemented through side holes 858 which are formed at the sidewall 816. The side holes 858 may be connected with an exhaust. duct 120. In this embodiment, the exhaust of the purge gas may be implemented through one of the exhaust port 854 or the side holes 858.

The heating wire 820 is a heating element. The heating wires 820 may be arranged in a plurality rows of verticality and horizontality on concentric circles around a rotation center of the substrate susceptor 200. The heating wire are arranged in a plurality rows of verticality and horizontality at the interior space 802 to remedy temperature falloff of the substrate susceptor 200 caused by pumping of a chamber edge portion. In this embodiment, the heating wires 820 may be arranged in two vertical direction and in five horizontal direction.

The heater member 800 may discretely control the heating wires 820 by each sector to maintain temperature uniformity of the substrate susceptor 200. The temperature control by sectors for the heating wires 820 may be performed in accordance with temperature value of temperature sensors installed on an inner surface of the substrate susceptor 200.

The heating wire supporters 830 are members for sustaining the heating wire 820, and are provided for preventing the heating wire 820 from drooping and twisting by thermal expansion of the heating wire 820.

The heating wire supporter 830 may be formed for the heating wire 820 at regular lengths or regular angles. The heating wire supporter 830 may have a concave support surface 832 which is formed along a latitudinal direction of the heating wire 820 to secure flexibility for thermal expansion of the heating wire 820. Length of the support surface 832 may be twice or three times of the heating wire diameter. As shown in FIG. 6, the heating wire supporter 830 can stably sustain the heating wire 820 even if a radius of the heating wire 830 is enlarged by thermal expansion of the heating wire 820.

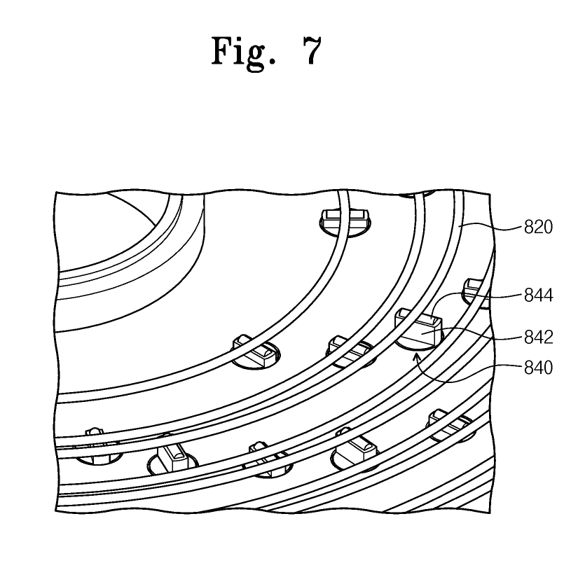

FIG. 7 illustrates another embodiment of the heating wire supporter.

Referring to FIG. 7, the heating wire supporter 840 may include a support block 842 and a support bar 844 installed on an upper surface of the support block 842. The support bar 844 may be formed of bar shape in point contact with the heating wire 820 to minimize contact area with the heating wire 820 and prevent the heating wire supporter 840 from broken by high heat of the heating wire. The support bar 844 may be formed of the same material as the heating wire 820.

As the above description is just for illustratively describing the inventive concepts, it will be available to those skilled in the art that various changes and modifications may be made without departing from the spirits and scopes of the inventive concepts. Therefore, it should be understood that the above embodiments are not limiting but illustrative. The scopes of the inventive concepts shall not be restricted or limited by the foregoing description. The scopes of the inventive concepts are to be determined by following claims, and it should be understood that the inventive concepts within their equivalents scope may belong to the scopes of the inventive concepts.

1. A substrate processing apparatus comprising:
a process chamber;
a substrate susceptor installed in the process chamber and connected with a rotation axis to be rotated, wherein a plurality of substrates are laid at the same level on the susceptor;
a heater member disposed on a lower surface of the substrate susceptor; and
a splay member splaying gas on an entire processing surface of the substrates from locations corresponding to the plurality of the substrates,
wherein the heater member has an interior space and heating wires for heating the substrate susceptor are arranged in a plurality rows of horizontality and verticality on the concentric circles around the rotation axis in the interior space.

2. The substrate processing apparatus of claim 1, wherein the heater member further comprises heating wire supporters sustaining the heating wire to prevent the heating wire from drooping and twisting by thermal expansion of the heating wire.

3. The substrate processing apparatus of claim 2, wherein the heating wire supporters comprises concave support surface formed along a latitudinal direction of the heating wire to secure flexibility for the thermal expansion of the heating wire.

4. The substrate processing apparatus of claim 2, wherein the heating wire supporter comprises a support block; and
a support bar having bar shape and formed on the upper surface of the support block, the support bar being in point contact with the heating wire to minimize a contact area with the heating wire, thereby preventing heat loss and preventing the heating wire supporter from broken by high heat of the heating wire.

5. The substrate processing apparatus of claim 4, wherein the support bar is formed of the same material as the heating wire.

6. The substrate processing apparatus of claim 4, wherein the support bar is provided along a latitudinal direction of the heating wire.

7. The substrate processing apparatus of claim 1, wherein the heater member further comprises a housing provided by an upper wall, a lower wall and sidewalls to isolate the interior space where the heating wire is arranged from an interior of the process chamber.

8. The substrate processing apparatus of claim 7, wherein the heater member further comprises a supply port provided to the lower wall and supplying purge gas into the interior space to prevent the process gas from permeating into the interior space.

9. The substrate processing apparatus of claim 8, wherein the heater member further comprises an exhaust port provided to the lower wall, wherein the purge gas supplied into the interior space through the supply port is exhausted through the exhaust port.

10. The substrate processing apparatus of claim 8, wherein the heater member comprises side holes provided to the sidewall of the housing, wherein the purge gas supplied into the interior space through the supply port is exhausted through the side holes.

11. The substrate processing apparatus of claim 1, wherein the upper wall is formed of quartz material capable of penetrating a radiant heat emitted from the heating wire.

12. The substrate processing apparatus of claim 1, wherein a radiant heat transmission space is formed between the substrate susceptor and the heater member to transmit the heat of the heating wire by a radiation mode.

13. A heater member for heating a substrate susceptor comprising:
a housing having an interior space provided by an upper wall, a lower wall and sidewalls and isolated from an exterior environment; and
heating wires for heating the substrate susceptor arranged in a plurality rows of horizontality and verticality on the concentric circles around a center of the substrate susceptor in the interior space.

14. The heater member of claim 13, further comprising:
heating wire supporters sustaining the heating wire to prevent the heating wire from drooping and twisting by thermal expansion of the heating wire,
wherein the heating wire supporter comprises concave support surface formed along a latitudinal direction of the heating wire to secure flexibility for the thermal expansion of the heating wire.

15. The heater member of claim 13, further comprising:
heating wire supporters sustaining the heating wire to prevent the heating wire from drooping and twisting by thermal expansion of the heating wire,
wherein the heating wire supporter comprises a support block; and
a support bar having bar shape and formed on the upper surface of the support block, the support bar being in point contact with the heating wire to minimize a contact area with the heating wire and prevent the heating wire supporter from broken by high heat of the heating wire.

16. The heater member of claim 13, further comprising:
a supply port supplying purge gas into the interior space to prevent the process gas from permeating into the interior space; and
an exhaust port where the purge gas supplied into the interior space through the supply port is exhausted.
